(19) United States
(12) Patent Application Publication
(10) Pub. No.: US 2026/0293297 A1
(43) Pub. Date: Sep. 24, 2026

(54) MULTI-GATE TRANSISTOR

(71) Applicant: Taiwan Semiconductor Manufacturing Company, Ltd., Hsinchu (TW)

(72) Inventors: Chiao-Ti Huang, New Taipei City (TW); Ka-Hing Fung, Hsinchu County (TW); Chi-An Wang, Hsinchu City (TW)

(21) Appl. No.: 19/287,310

(22) Filed: Jul. 31, 2025

Related U.S. Application Data
(60) Provisional application No. 63/774,990, filed on Mar. 20, 2025.

(51) Int. Cl. H10D 84/83; H10D 30/00; H10D 30/01; H10D 62/10; H10D 64/01; H10D 64/27; H10D 64/66; H10D 84/01

(52) U.S. Cl. CPC H10D 84/83138; H10D 30/0191; H10D 30/0197; H10D 30/502; H10D 64/017; H10D 64/018; H10D 64/518; H10D 64/667; H10D 64/675; H10D 84/0142; H10D 84/8311; H10D 84/832; H10D 62/121

(57) ABSTRACT

A semiconductor device according to the present disclosure includes a first base fin and a second base fin extending from a substrate, an isolation feature disposed between the first base fin and the second base fin, a first dummy epitaxial layer disposed on the first base fin, a second dummy epitaxial layer disposed on the second base fin, a first insulator layer over the first dummy epitaxial layer, a second insulator layer over the second dummy epitaxial layer, a first source/drain feature disposed on the first insulator layer, a second source/drain feature disposed on the second insulator layer. A thickness of the first dummy epitaxial layer measured from a top surface of the first base fin is smaller than a thickness of the second dummy epitaxial layer measured from a top surface of the second base fin.

### PRIORITY DATA

The present application claims the benefit of U.S. Provisional Application No. 63/774,990, filed Mar. 20, 2025, the entirety of which is herein incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT). Because the channel region of a GAA transistor may include nanowires or nanosheets and its configuration resembles a bridge, a GAA transistor may also be referred to a multi-bridge-channel (MBC) transistor, a nanowire transistor, or a nanosheet transistor. The nanosheets and nanowires may be generally referred to as nanostructures.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a first example method for forming a semiconductor device having more than one device region, according to one or more aspects of the present disclosure.

FIGS. 2-19 illustrate fragmentary cross-sectional and perspective views of a precursor structure during various fabrication stages in the method of FIG. 1, according to one or more aspects of the present disclosure.

FIG. 20 illustrates a flowchart of a second example method for forming a semiconductor device having more than one device region, according to one or more aspects of the present disclosure.

FIGS. 21-30 illustrate fragmentary cross-sectional and perspective views of a precursor structure during various fabrication stages in the method of FIG. 20, according to one or more aspects of the present disclosure.

FIG. 31 illustrates a precursor structure having an isolation structure, according to one or more aspects of the present disclosure.

FIG. 32 illustrates a semiconductor device formed from the precursor structure shown in FIG. 31, according to one or more aspects of the present disclosure,

FIG. 33 illustrates a schematic top view of a semiconductor structure that includes first type devices implemented in a first device region and second type devices implemented in a second device region, according to one or more aspects of the present disclosure.

FIG. 34 illustrates a cross-sectional view of the semiconductor structure in FIG. 33, according to one or more aspects of the present disclosure.

FIG. 35 illustrates a schematic top view of a semiconductor structure that includes second type devices implemented in a first device region and first type devices implemented in a second device region, according to one or more aspects of the present disclosure.

FIG. 36 illustrates a cross-sectional view of the semiconductor structure in FIG. 35, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. As used herein, source/drain region(s) may refer to a source or a drain, individually or collectively, dependent upon the context.

Multi-gate devices have been introduced to improve gate control by increasing gate-channel coupling, reducing off-state current, and reducing short-channel effects (SCEs). While multi-gate devices are advantageous in many ways, their intricate three-dimensional structure and thin dielectric layers may lead to increased parasitic capacitance. With respect to multi-gate devices, both primary capacitance and secondary capacitance contribute to overall parasitic capacitance. The primary capacitance refers to the capacitance between the channel and the gate electrode. The secondary capacitance refers to the capacitance between the gate and source, the gate and the drain, and between contact structures. In general, the primary capacitance contributes more to the overall capacitance than the secondary capacitance.

The present disclosure provides processes and structures to provide GAA transistors with different capacitances. In an example process, a dummy gate stack is formed over a channel region disposed between two source/drain features. The channel region includes channel layers interleaved by sacrificial semiconductor layers or channel layers interleaved by dielectric interposers. After source/drain trenches are formed and source/drain features are deposited in the source/drain trenches, the dummy gate stack is removed to expose a topmost channel layer. The topmost channel layer or the topmost channel layers are then selectively removed using a wet etch process. The remaining channel layers are then released as channel members extending between source/drain features. A gate structure is then formed to wrap around the channel members. In some alternative embodiments, the selective removal of the topmost channel layer(s) and the formation of the gate structure are performed after formation of fin-shaped isolation structures, such as continuous poly on diffusion edge (CPODE) features. Because the selective removal of the topmost channel layer(s) includes use a wet etch process, the leftover channel layer(s) may include a rounded profile. The removal of the topmost channel layer substantially reduces the primary capacitance, resulting in a lower overall device capacitance.

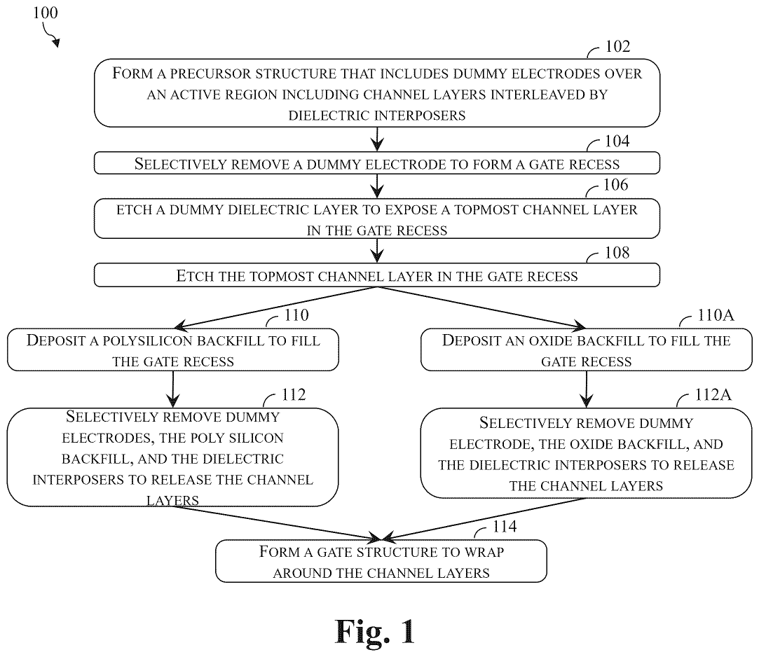

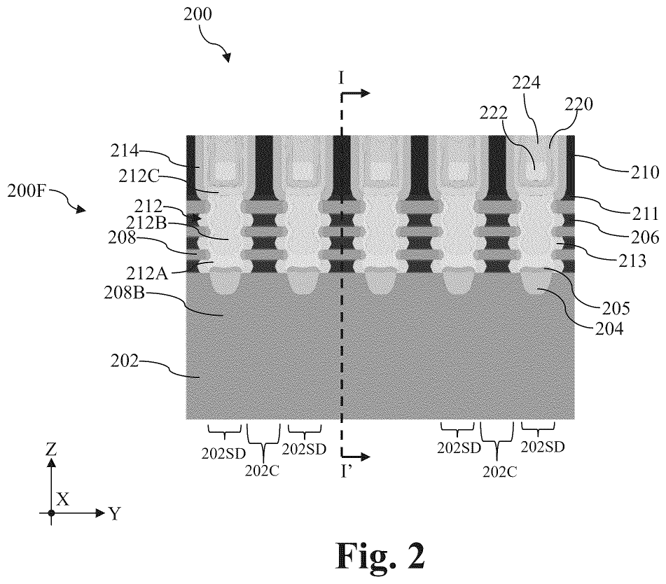

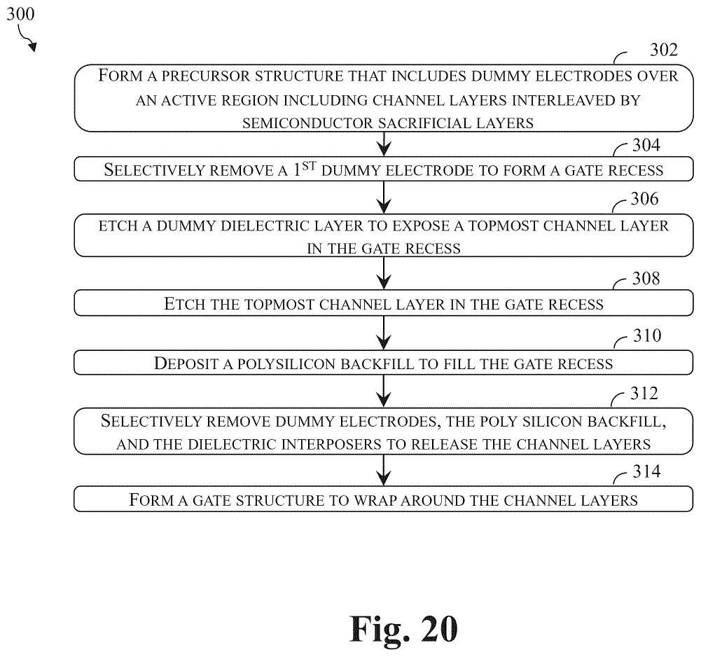

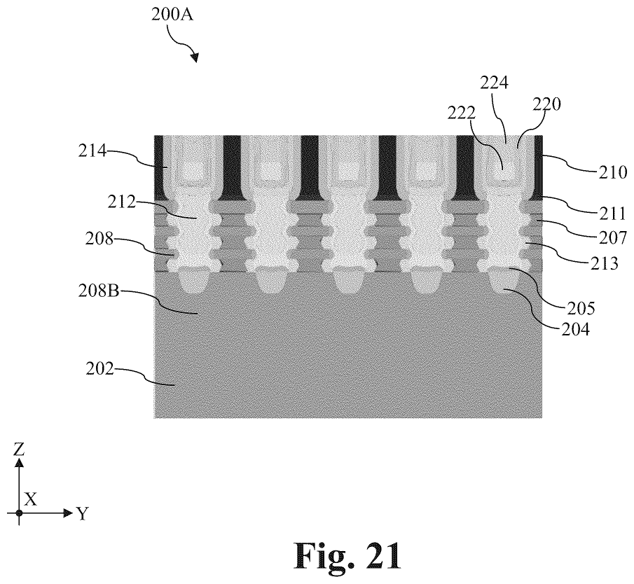

The various aspects of the present disclosure will now be described in more detail with reference to the figures. FIGS. 1 and 20 illustrate flowcharts of a method 100 and a method 300 of forming a semiconductor device. Each of method 100 and method 300 is merely an example and is not intended to limit the present disclosure to what is explicitly illustrated in method 100 or method 300. Additional steps may be provided before, during and after method 100 or method 300, and some steps described can be replaced, eliminated, or moved around for additional embodiments of the methods. Not all steps are described herein in detail for reasons of simplicity. Method 100 is described below in conjunction with FIGS. 2-19, which illustrate fragmentary cross-sectional views of a precursor structure 200 at different stages of fabrication according to embodiments of method 100. Method 300 is described below in conjunction with FIGS. 21-30, which illustrate fragmentary cross-sectional views of a precursor structure 200 at different stages of fabrication according to embodiments of method 300. Because a semiconductor device will be formed from the precursor structure 200, the precursor structure 200 may be referred to as a semiconductor device 200 as the context requires. Throughout FIGS. 2-19 and 21-36, the Y direction, the X direction, and the Z direction are perpendicular to one another and are used consistently. For example, the Y direction in one figure is parallel to the Y direction in a different figure. Additionally, throughout the present disclosure, like reference numerals are used to denote like features.

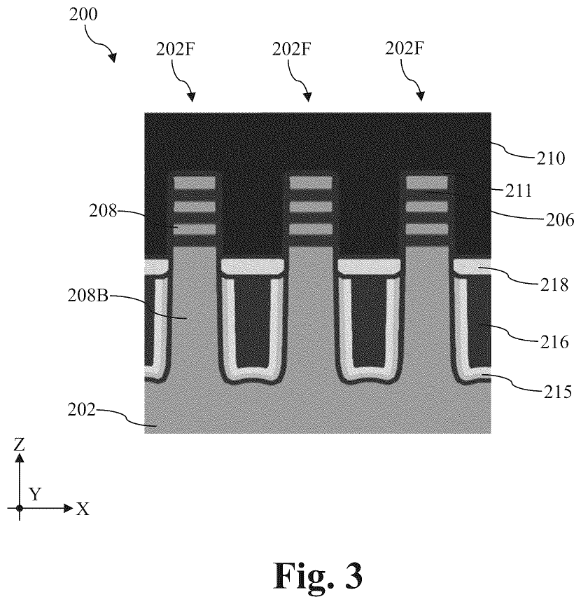

Referring to FIGS. 1, 2 and 3, method 100 includes a block 102 where a precursor structure 200 is formed. As shown in FIG. 2, the precursor structure 200 includes dummy gate electrodes 210 over an active region 202F that includes channel layers 208 interleaved by dielectric interposers 206. Referring to FIGS. 2 and 3, the active region 202F is disposed over a substrate 202 and includes channel regions 202C and source/drain regions 202SD. Source/drain regions 202SD of the fin-shaped structure 202F are recessed to form source/drain trenches and source/drain features 212 are formed in the source/drain trenches. Each of the source/drain features 212 interfaces end sidewalls of the channel layers 208 over the channel regions 202C. The dielectric interposers 206 are spaced apart from the source/drain features 212 by a plurality of inner spacer features 213. Each of the source/drain features 212 is vertically spaced apart from the substrate 202 by an undoped semiconductor feature 204 and a bottom isolation layer 205. A dummy gate electrode 210 is disposed over the channel layers 208 in each of the channel regions 202C. A gate spacer 214 is disposed along sidewalls of the dummy gate electrode 210. A contact etch stop layer (CESL) 220 is disposed along sidewalls of the gate spacer 214 and a top surface of the source/drain feature 212. An interlayer dielectric (ILD) layer 222 is disposed over the CESL 220. A dielectric cap layer 224 is disposed over the ILD layer 222. Sidewalls of the ILD layer 222 and the dielectric cap layer 224 are spaced apart from the gate spacer 214 by the CESL 220. Reference is made to FIG. 3, which illustrates a dummy gate electrode 210 wrapping over three active regions 202F. Each of the active region 202F includes a base fin 208B that is continuous from the substrate 202 and channel layers 208 stacked over the base fin 208B. Each of the active regions 202F extend lengthwise along the Y direction. Along the X direction, the base fins 208B of the active regions 202F are separated by isolation features 216. In some embodiments represented in FIG. 3, the isolation features 216 are spaced apart from the base fins 208B and the substrate 202 by a liner 215 and are capped by a protective layer 218. In some implementations, the protective layer 218 is disposed over the liner 215 and the isolation feature 216. The isolation feature 216 may also be referred to as a shallow trench isolation (STI) feature 216. A dummy dielectric layer 211 is deposited over the protective layer 218 and the active region 202F before the deposition of the dummy gate electrode 210.

In one embodiment, the substrate 202 may be a silicon (Si) substrate. In some other embodiments, the substrate 202 may include other semiconductor materials such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure or a germanium-on-insulator (GeOI) structure. In some embodiments, the substrate 202 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion.

In some implementations, the channel layers 208 are formed of silicon (Si) and the dielectric interposers 206 are formed of silicon oxide. The undoped semiconductor feature 204 may include undoped silicon or undoped silicon germanium. The bottom isolation layer 205 may include silicon nitride. Depending on the design, the source/drain features 212 may be either n-type or p-type. When they are n-type, they may include silicon (Si) doped with an n-type dopant such as phosphorus (P) or arsenic (As). When they are p-type, they may include silicon germanium (SiGe) and a p-type dopant, such as boron (B). The source/drain features 212 may include multiple epitaxial layers. In some embodiments represented in FIG. 2, each of the source/drain features 212 includes a first epitaxial layer 212A, a second epitaxial layer 212B over the first epitaxial layer and a third epitaxial layer 212C over the first epitaxial layer and the second epitaxial layer. In these embodiments, the first epitaxial layer interfaces the end sidewalls of the channel layers 208, the second epitaxial layer is highly doped to reduce contact resistance, and the third epitaxial layer services to protect the first epitaxial layer and the second epitaxial layer. A concentration of a dopant, either n-type or p-type, in the second epitaxial layer is higher than a dopant concentration in the first epitaxial layer or in the third epitaxial layer.

In some embodiments, the inner spacer features 213 may include silicon nitride, silicon carbonitride, silicon oxycarbide, silicon oxycarbonitride, or silicon oxynitride. The gate spacer 214 may include silicon nitride, silicon carbonitride, silicon oxycarbide, silicon oxycarbonitride, or silicon oxynitride. In some embodiments, the gate spacer 214 may include more than one layer. For example, the gate spacer 214 may include a first layer to interface the dummy gate electrode 210 and a second layer spaced apart from the dummy gate electrode 210 by the first layer. The first layer and the second layer may have different dielectric constants. In some instances, a dielectric constant of the first layer is greater than a dielectric constant of the second layer. The CESL 220 may include silicon nitride or silicon oxynitride. The interlayer dielectric (ILD) layer 222 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The dielectric cap layer 224 may share a similar composition with the CESL 220. The isolation features 216 may include silicon oxide, silicon oxynitride, fluorine-doped silicate glass (FSG), a low-k dielectric, or a combination thereof. The liner 215 may include silicon oxide, silicon nitride, silicon oxycarbide, silicon carbonitride, or a combination thereof. The liner 215 may include multiple sublayers with different compositions. The protective layer 218 may include silicon oxycarbide, silicon carbonitride, silicon nitride, or a combination thereof.

The dummy gate electrode 210 (or dummy electrode 210) is formed of polysilicon and is spaced apart from a top surface of the topmost channel layer 208 and sidewalls of the channel layers 208 by the dummy dielectric layer 211. In some embodiments, the dummy dielectric layer 211 includes silicon oxide. The dummy dielectric layer 211 and the dummy electrode 210 may be regarded as a dummy gate stack, which serves a placeholder structure to endure process steps before it is replaced with a metal gate structure. As shown in FIG. 3, a dummy gate stack, including the dummy electrode 210 and the dummy dielectric layer 211 may wrap over more than one active regions 202F

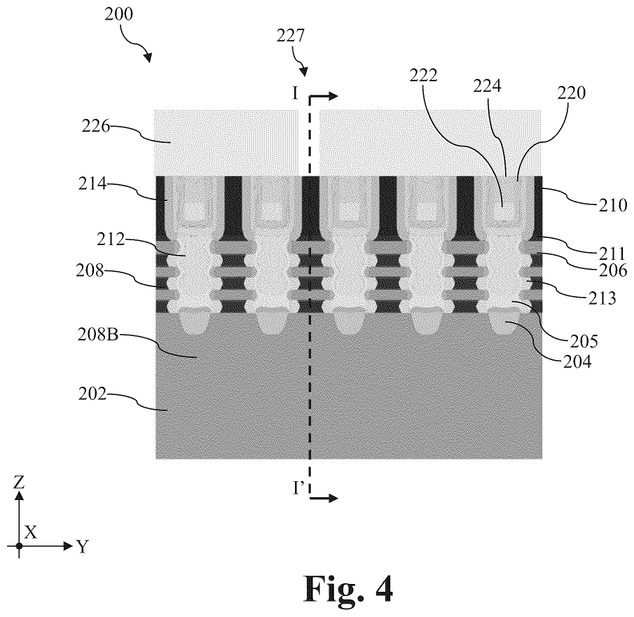

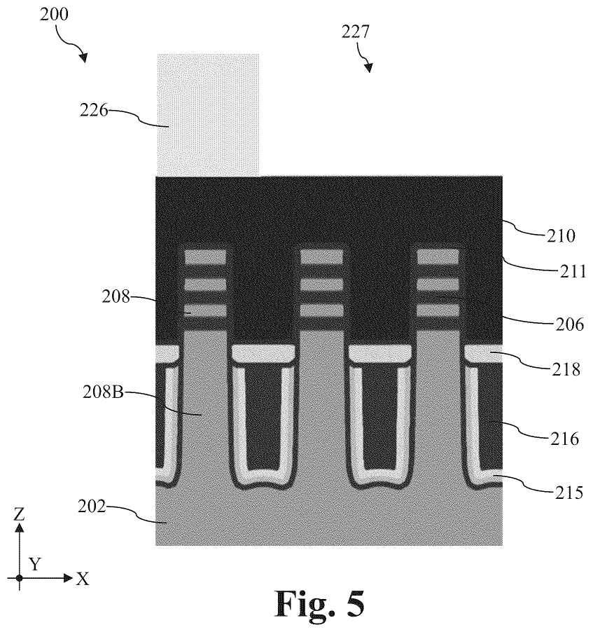

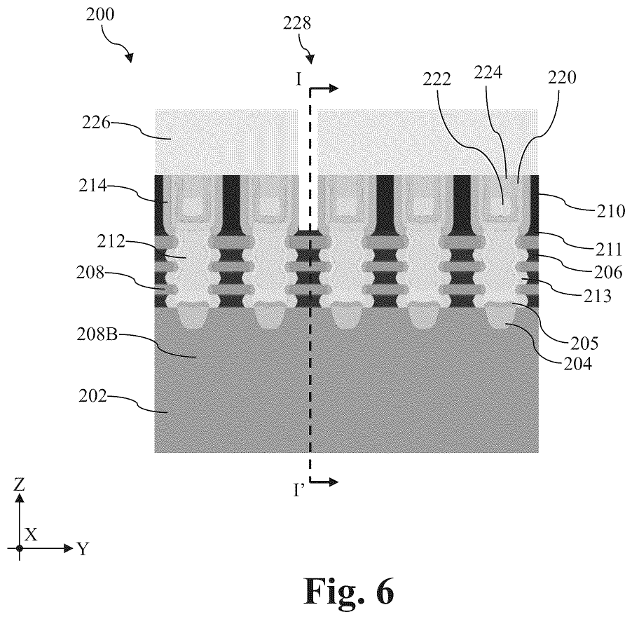

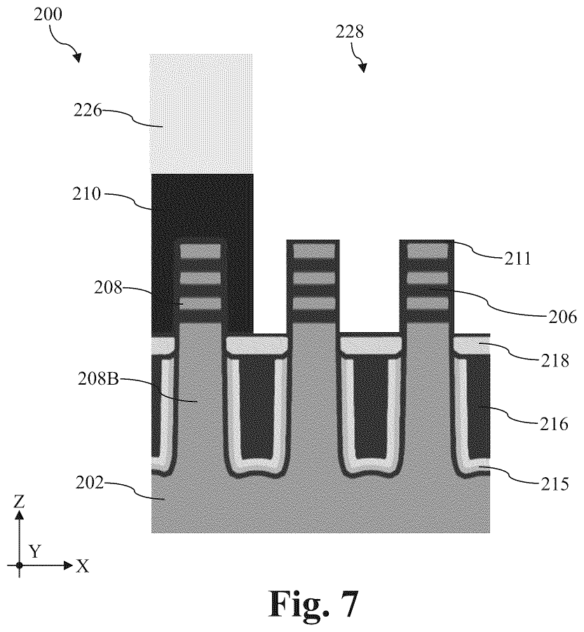

Referring to FIGS. 1 and 4-7, method 100 includes a block 104 where a first dummy electrode 210 is selectively removed to form a gate recess 228. In an example process, a hard mask layer 226 is deposited over the precursor structure 200, as shown in FIG. 4. In some embodiments, the hard mask layer 226 may include silicon nitride, silicon oxide, bottom antireflective coating (BARC), or a combination thereof. Then photolithography processes and etch processes are performed to form an opening 227 in the hard mask layer 226. FIG. 5 is a fragmentary cross-sectional view along line I-I′ in FIG. 4. As illustrated in FIGS. 4 and 5, the opening 227 exposes a first dummy electrode 210. Reference is now made to FIG. 6. Using the patterned hard mask layer 226 as an etch mask, a dry etch is performed to remove the dummy electrode 210. An example dry etch process for block 104 may implement a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the dummy dielectric layer 211 may serve as an etch stop layer or help provide etch termination signal at block 104. Referring to FIG. 6, the first dummy electrode 210 exposed in the opening 227 is removed, leaving behind the dummy dielectric layer 211 covering a top surface of the topmost channel layer 208. Removal of the first dummy electrode 210 forms a gate recess 228 defined between two gate spacers 214. FIG. 7 is a fragmentary cross-sectional view along line I-I′ in FIG. 6. FIG. 7 illustrates that the dummy electrode 210 is removed and the dummy dielectric layer 211 is exposed.

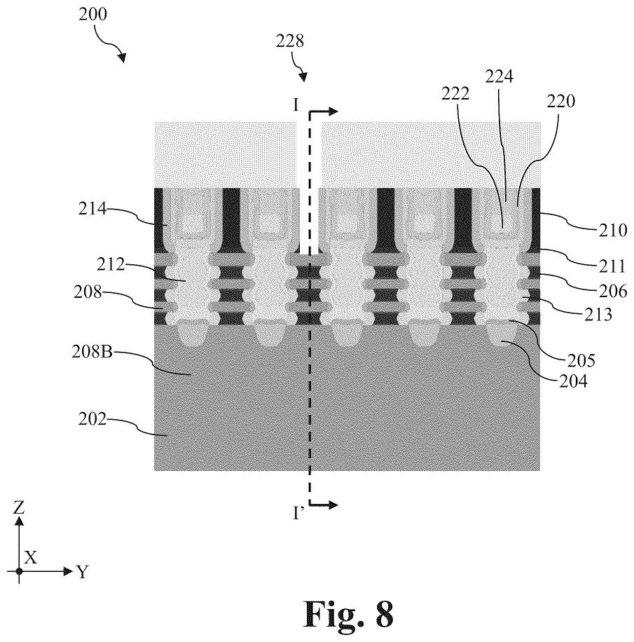

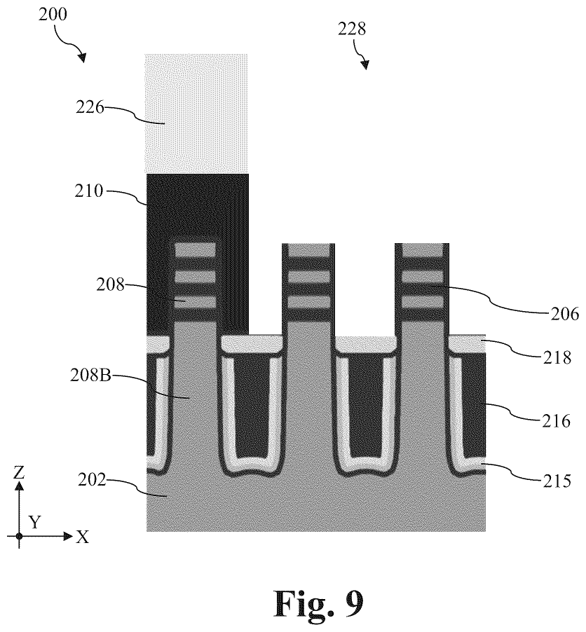

Referring to FIGS. 1, 8 and 9, method 100 includes a block 106 where a dummy dielectric layer 211 is etched to expose a topmost channel layer 208. In some embodiments, the etch processes are highly selective and the etch process configured to etch the dummy electrode 210 at block 106 does not etch the dummy dielectric layer 211 effectively. Method 100 includes a separate block 106 for the selective etching of the dummy dielectric layer 211. In some embodiment, the etching at block 106 is a dry etch process that implements oxygen (O₂), hydrogen (H₂), argon (Ar), a fluorine-carbon gas (e.g., CF₄, CH₂F₂, CHF₃, C₄F₈, C₅F₈, and/or C₂F₆), or a combination thereof. FIG. 9 is a fragmentary cross-sectional view along line I-I′ in FIG. 8. As illustrated in FIG. 9, because the dry etch process at block 106 is anisotropic, the portion of the dummy dielectric layer 211 over a top surface of the topmost channel layers 208 and a top surface of the protective layer 218 is removed while the portion of the dummy dielectric layer 211 along sidewalls of the channel layers and the dielectric interposers 206 may remain.

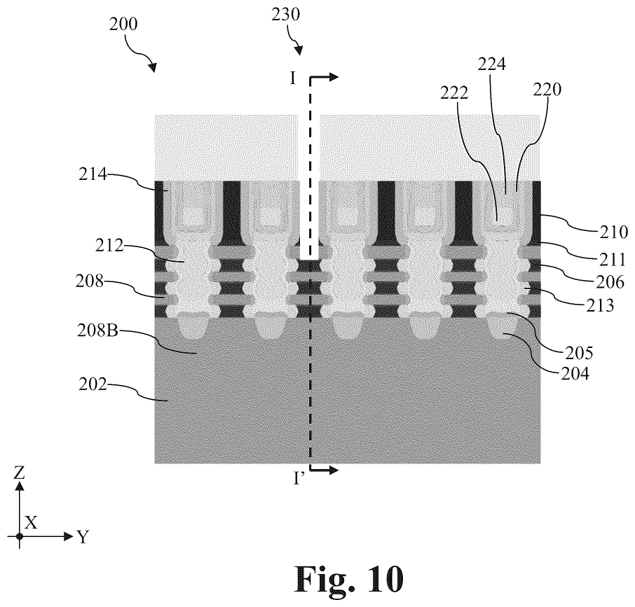

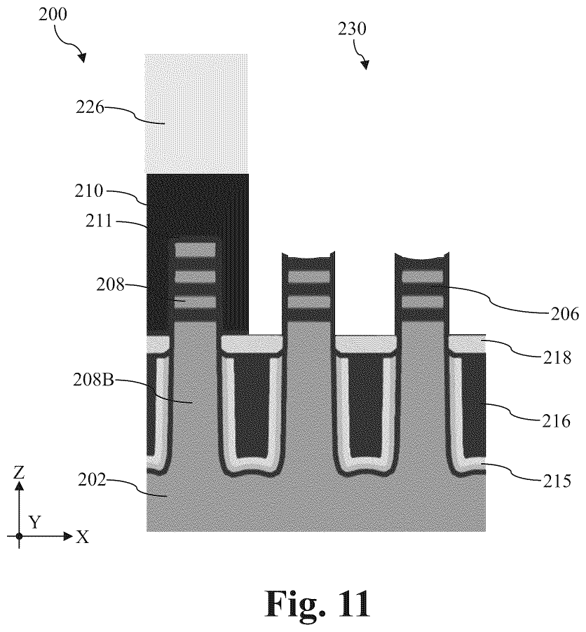

Referring to FIGS. 1, 10 and 11, method 100 includes a block 108 where the topmost channel layer 208 is selectively removed in the gate recess 228. After operations at block 106 expose the topmost channel layers 108 in the gate recess 228, a dry etch is performed to etch through the topmost channel layers 108 to form an extended gate recess 230. In some embodiments, because a composition of the dummy electrode 210 and a composition of the channel layers 208 are similar, the dry etch process at block 108 may be similar to the dry etch process at block 104. As shown in FIG. 10, because the etch processes at blocks 104, 106 and 108 are all directional, sidewalls of the extended gate recess 230 are substantially perpendicular. FIG. 11 is a fragmentary cross-sectional view along line I-I′ in FIG. 10. Because the dry etch at block 108 etches the topmost channel layers 208 faster than it etches the dummy dielectric layer 211 or the dielectric interposers 206, the etching of the topmost channel layers 208 may leave a concave top surface over the exposed dielectric interposers 206.

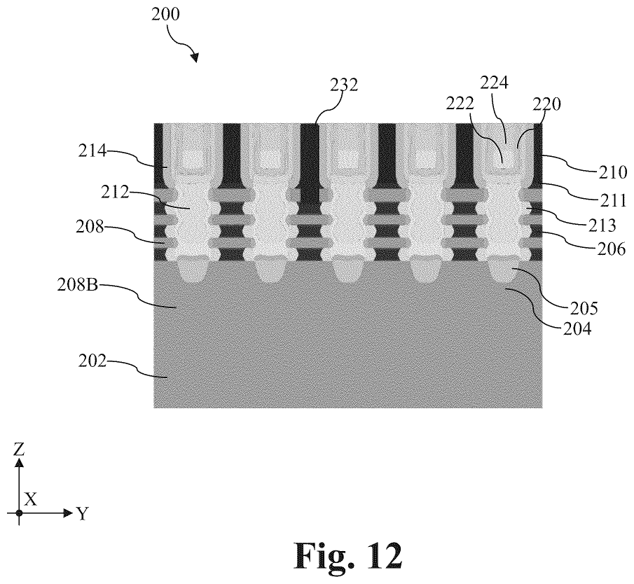

Referring to FIGS. 1 and 12, method 100 includes a block 110 where a polysilicon backfill 232 is deposited to fill the gate recess 228. In order to provide a uniform etching environment and to enlarge process window, the polysilicon backfill 232 is deposited in the extended gate recess 230. The composition of the polysilicon backfill 232 is similar to the composition of the dummy electrodes 210. In an example process, the polysilicon backfill 232 may be deposited using vapor-phase epitaxy (VPE), ultra-high vacuum CVD (UHV-CVD), or molecular beam epitaxy (MBE). Deposition of the polysilicon backfill 232 may include use of silicon-containing precursors, such as silane, disilane, dichlorosilane, trichlorosilane. Because the deposition is selective to semiconductor surfaces, the exposed surfaces of the etched channel layers 208 help a bottom-up deposition of the polysilicon backfill 232. While not illustrated explicitly, a planarization process, such as a chemical mechanical polishing (CMP) process, is performed to remove excess polysilicon backfill 232, leaving a planar top surface.

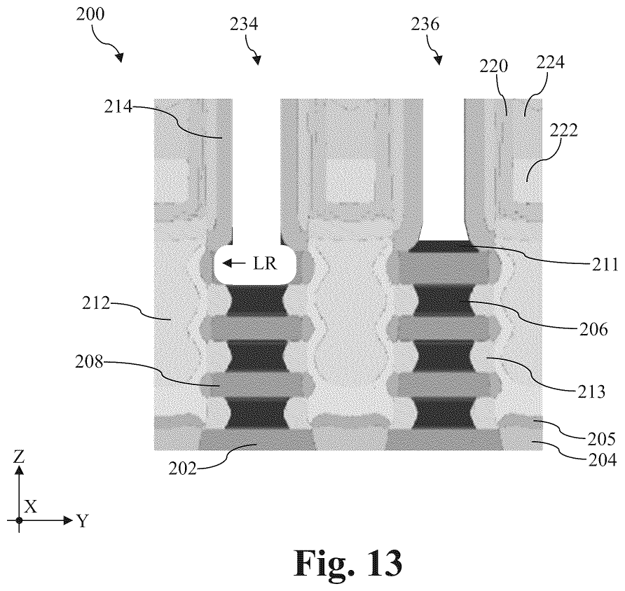

Referring to FIGS. 1, 13 and 14, method 100 includes a block 112 where dummy electrodes 210, the polysilicon backfill 232, and dielectric interposer 206 are selectively removed to release the channel layers 208. With the polysilicon backfill 232 formed at block 110 to provide a uniform environment, a wet etch process is performed at block 112 to selectively and isotropically remove the polysilicon backfill 232 and other dummy electrodes 210. In some embodiments, the wet etch at block 112 may include use of a tetramethylammonium hydroxide (TMAH) solution, a potassium hydroxide (KOH) solution, hydrofluoric acid, nitric acid, or a combination thereof. FIG. 13 illustrates a cross-sectional view of the precursor structure 200. As shown in FIG. 13, the removal of the polysilicon backfill 232 form a first gate opening 234 and the removal of the dummy electrode 210 forms a second gate opening 236. Because the wet etch is selective to the channel layers 208, the wet etch may attack the topmost channel layer 208 under the gate spacer 214, forming a lateral recess LR. The lateral recess LR undercuts the gate spacer 214. Referring still to FIG. 13, the topmost channel layer 208 is substantially removed from the first gate opening 234 while the topmost channel layer 208 remains in the second gate opening 236.

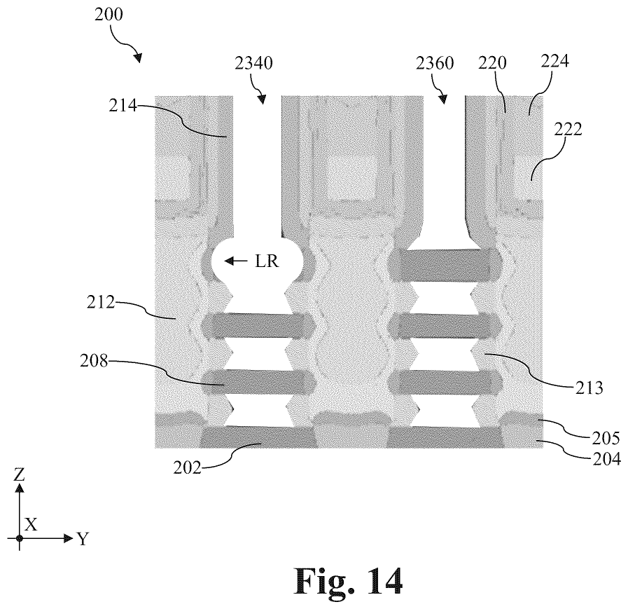

Referring to FIG. 14, after the removal of the polysilicon backfill 232 and the dummy electrodes 210, the dielectric interposers 206 and the dummy dielectric layer 211 are selectively removed. At block 112, a separate etch process may be performed to selectively remove the dielectric interposers 206 and the dummy dielectric layer 211. For example, a selective wet etch process or a selective dry etch process may be performed to remove the dielectric interposers 206 and the dummy dielectric layer 211. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. Reference is made to FIG. 14. The selective removal of the dielectric interposers 206 in the first gate opening 234 (shown in FIG. 13) forms a first gate trench 2340 that includes the lateral recess LR. The selective removal of the dielectric interposers 206 and the dummy dielectric layer 211 in the second gate opening 236 (shown in FIG. 13) forms a second gate trench 2360.

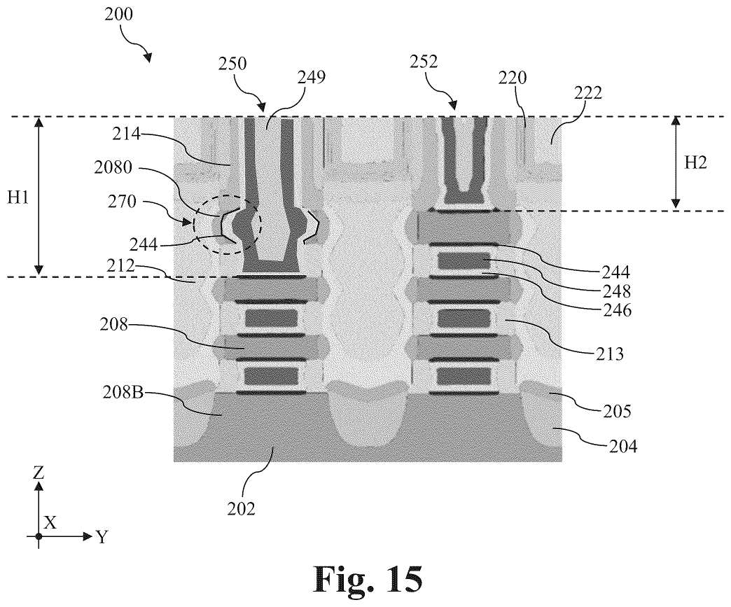

Referring to FIGS. 1 and 15, method 100 includes a block 114 where a gate structure is formed to wrap around the channel layers 208. Depending on whether the topmost channel layer 208 is etched away, the gate structure formed at block 114 may include a first gate structure 250 formed in the first gate trench 2340 and a second gate structure 252 formed in the second gate trench 2360. Each of the first gate structure 250 and the second gate structure 252 includes an interfacial layer 244 interfacing the channel layers 208 and the substrate 202, a gate dielectric layer 246 over the interfacial layer 244, a gate electrode layer 248 over the gate dielectric layer 246, and a gate metal fill 249 over the gate electrode layer 248. The interfacial layer 244 may include a dielectric material such as silicon oxide, hafnium silicate, or silicon oxynitride. The interfacial layer 244 may be formed by chemical oxidation, thermal oxidation, atomic layer deposition (ALD), chemical vapor deposition (CVD), and/or other suitable method. The gate dielectric layer 246 may include a high-k dielectric material, such as hafnium oxide. Alternatively, the gate dielectric layer 246 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. Because the gate dielectric layer 246 is formed of a high-k dielectric material, its dielectric constant is greater than that of the ILD layer 222 or the isolation feature 216. The gate dielectric layer 246 may be formed by ALD, physical vapor deposition (PVD), CVD, oxidation, and/or other suitable methods.

The gate electrode layer 248 of the first gate structure 250 and the second gate structure 252 may include a multi-layer structure, such as various combinations of a metal layer with a selected work function to enhance the device performance (work function metal layer), a liner layer, a wetting layer, an adhesion layer, a metal alloy or a metal silicide. In one embodiment, the electrode layer 248 includes a titanium-based material. By way of example, the gate electrode layer 248 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 248 may be formed by ALD, PVD, CVD, e-beam evaporation, or other suitable process. In various embodiments, a CMP process may be performed to remove excessive metal, thereby providing a substantially planar top surface of the gate structure. The gate metal fill 249 may include tungsten (W).

Both the first gate structure 250 and the second gate structure 252 include an interlayer portion and a top portion over the interlayer portion. The interlayer portion is disposed between two channel layers 208 or between a bottommost channel layer 208 and the substrate 202. The top portion extends upward from the topmost channel layer 208. In the depicted embodiments, the first gate structure 250 wraps around two channel layers 208 and the second gate structure 252 wraps around three channel layers 208. Because the first gate structure 250 wraps around one less channel layer 208, a first height H1 of the top portion of the first gate structure 250 is greater than a second height H2 of the top portion of the second gate structure 252. In some instances, the first height H1 is greater than the second height H2 by a difference between about 10 nm and about 30 nm. This difference is substantially equal to a sum of a thickness of the channel layer 208 and a spacing between two channel layers 208.

Due to presence of the lateral recess LR, the first gate structure 250 includes a lateral bulge 270 at the level of the recessed topmost channel layer 208. As shown in FIG. 15, the lateral bulge 270 includes a channel layer residue 2080, the interfacial layer 244 formed on the channel layer residue 2080, the gate dielectric layer 246, and the gate electrode 248. In some embodiments illustrated in FIG. 15, the gate spacer 214 is disposed directly over and interfaces the lateral bulge 270.

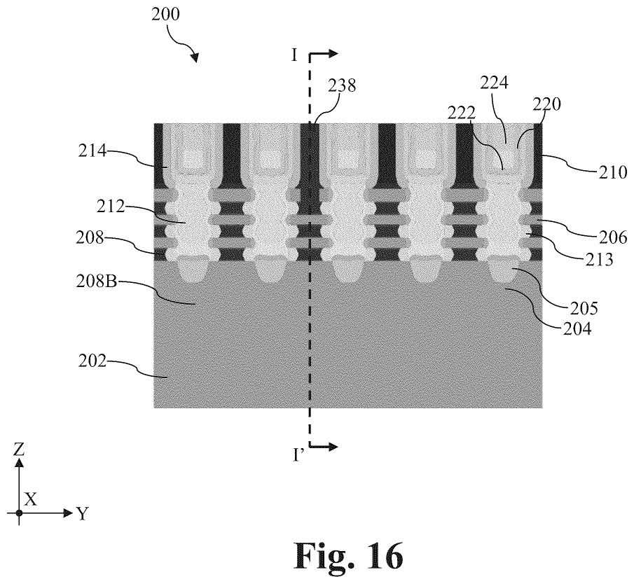

Method 100 in FIG. 1 also includes an alternative embodiment where operations at block 110 are replaced with those at block 110A and operations at block 112 are replaced with those at block 112A. Operations at blocks 110 and 112 represent embodiments where a polysilicon backfill is deposited to fill the gate recess after etching of the topmost channel layer. Operations at blocks 110A and 112A represent alternative embodiments where an oxide backfill is deposited to fill the gate recess after etching of the topmost channel layer. The alternative embodiments are described below in conjunction with FIGS. 16, 17, 18, and 19.

Referring to FIGS. 1 and 16, method 100 includes a block 110A where an oxide backfill 238 is deposited to fill the gate recess 228. The oxide backfill 238 may include silicon oxide and may be formed by depositing an oxide-based dielectric material using one or more deposition methods and planarizing the precursor structure 200 to remove the excess material. The oxide backfill 238 may be deposited using atomic layer deposition (ALD), chemical vapor deposition (CVD), or flowable chemical vapor deposition (FCVD). The planarization at block 110A may be performed using chemical vapor deposition (CMP).

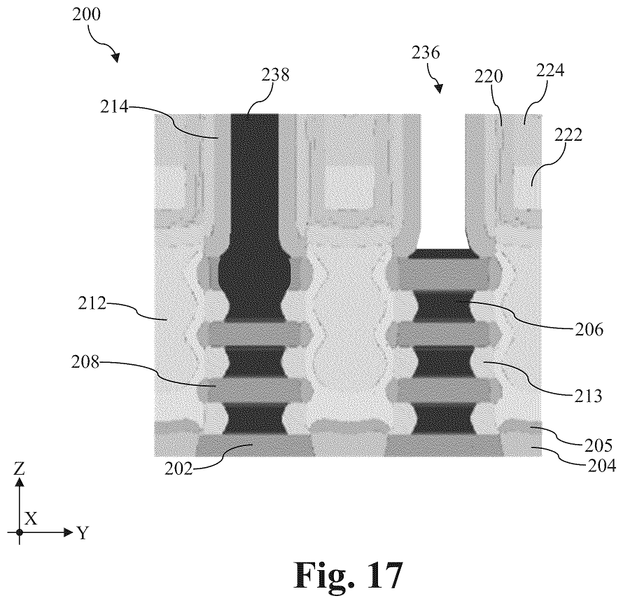

Referring to FIGS. 1, 17 and 18, method 100 includes a block 112A where dummy gate electrodes 210, the oxide backside 238, and dielectric interposer 206 are selectively removed to release the channel layers 208. With the oxide backfill 238 filling the gate recess 228 to protect the structures below, a wet etch process is performed at block 112A to selectively remove the dummy gate electrodes 210. In some embodiments, the wet etch at block 112A may include use of a tetramethylammonium hydroxide (TMAH) solution, a potassium hydroxide (KOH) solution, hydrofluoric acid, nitric acid, or a combination thereof. FIG. 17 illustrates a cross-sectional view of the precursor structure 200. As shown in FIG. 17, because the wet etch process is elective to polysilicon dummy gate electrodes 210, the oxide backfill 238 remains substantially unetched. The removal of the dummy gate electrode 210 forms the second gate opening 236.

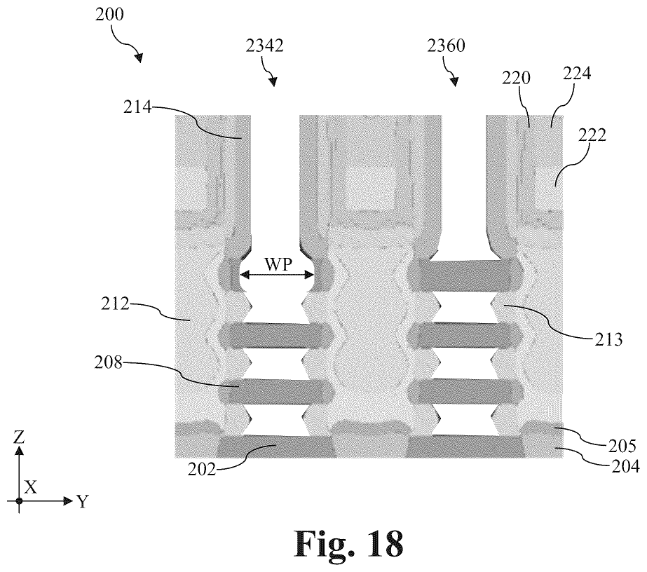

Referring to FIG. 18, after the removal of the dummy gate electrodes 210, the dielectric interposers 206, the oxide backfill 238, and the dummy dielectric layer 211 are selectively removed. At block 112A, a single etch process may be performed to selectively remove the dielectric interposers 206, the oxide backfill 238, and the dummy dielectric layer 211 due to their similar composition. For example, a selective wet etch process or a selective dry etch process may be performed to remove the dielectric interposers 206, the oxide backfill 238, and the dummy dielectric layer 211. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. Reference is made to FIG. 18. The selective removal of the oxide backfill 238 and the dielectric interposers 206 (shown in FIG. 17) forms a third gate trench 2342. The selective removal of the dielectric interposers 206 and the dummy dielectric layer 211 in the second gate opening 236 (shown in FIG. 13) forms a second gate trench 2360. It is noted that when the oxide backfill 238 is used, the removal of the oxide backfill 238 does not substantially etch the remaining portion of the topmost channel layer 208 laterally (along the Y direction). As a result, the lateral recess in the third gate trench 2342 is mild and only results in a widening portion (WP). Along the channel length direction (i.e., the Y direction), the widening portion WP has a width greater than a width of the portion between two gate spacers 214.

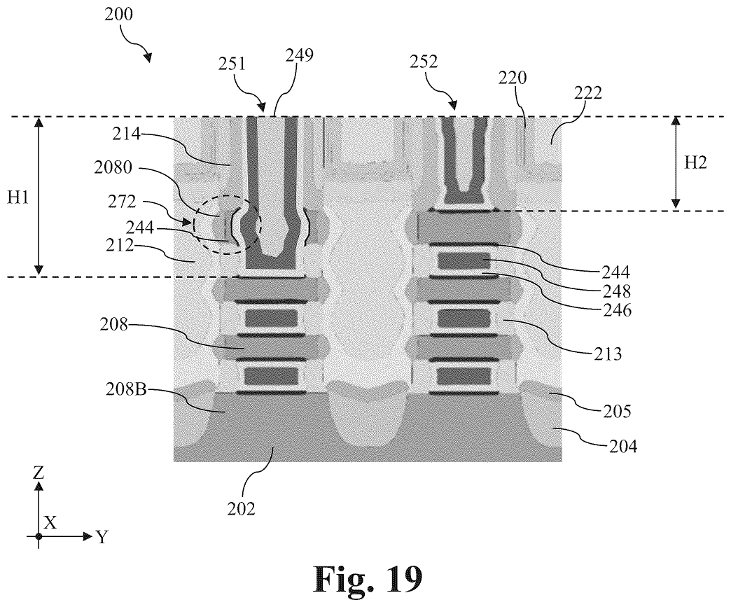

Referring to FIGS. 1 and 19, method 100 includes a block 114 where a gate structure is formed to wrap around the channel layers 208. Depending on whether the topmost channel layer 208 is etched away, the gate structure formed at block 114 may include a third gate structure 251 formed in the third gate trench 2342 and a second gate structure 252 formed in the second gate trench 2360. Compositions of the third gate structure 251 and the second gate structure 252 are similar to those of the first gate structure 250 and the second gate structure 252. For this reason, detailed description of the third gate structure 251 and the second gate structure 252 will not be repeated here.

Due to presence of the widening portion WP, the third gate structure 251 includes a bump 272 at the level of the recessed top most channel layer 208. As shown in FIG. 16, the bump 272 includes a channel layer residue 2080, the interfacial layer 244 formed on the channel layer residue 2080, the gate dielectric layer 246, and the gate electrode 248. In some embodiments illustrated in FIG. 19, only a portion of the gate spacer 214 vertically overlaps with the bump 272.

In method 100, the active region in the precursor structure 200 includes channel layers 208 interleaved by dielectric interposer 206. In some alternative embodiments, the channel layers 208 are interleaved by semiconductor sacrificial layers, not dielectric interposers. FIG. 20 includes a flowchart of a method 300 that is suitable for forming a semiconductor device from a precursor structure 200A that includes channel layers 208 interleaved by semiconductor sacrificial layers.

Referring to FIGS. 20 and 21, method 300 includes a block 302 where a precursor structure 200A is formed. As shown in FIGS. 20 and 21, the precursor structure 200A is similar to the precursor structure 200 shown in FIGS. 2 and 3, except that the dielectric interposers 206 in FIGS. 2 and 3 are replaced with semiconductor sacrificial layers 207. In some embodiments, the semiconductor sacrificial layers 207 are formed of silicon germanium (SiGe). The germanium content in the semiconductor sacrificial layers 207 allow them to be selectively removed to release the channel layers 208. Because the rest of the features in the precursor structure 200A are substantially similar to those in the precursor structure 200, their detailed descriptions will be omitted.

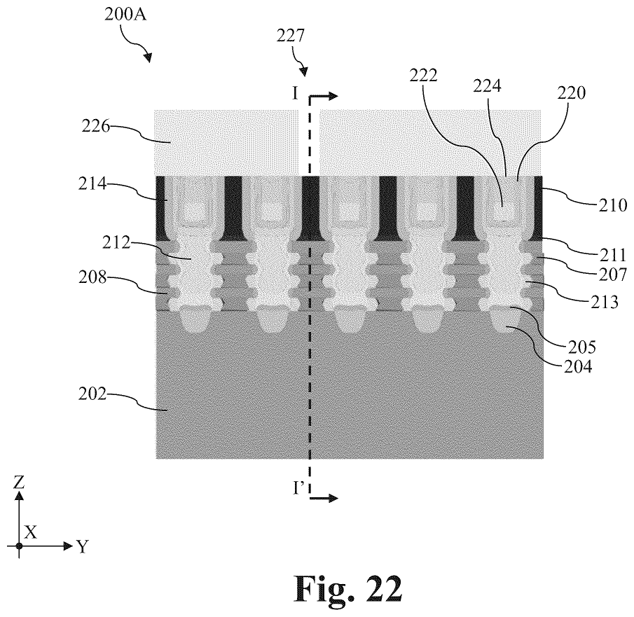

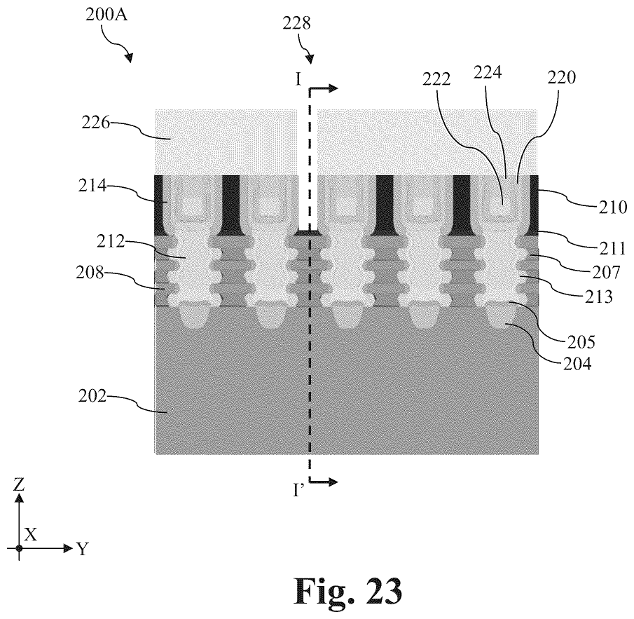

Referring to FIGS. 21, 22 and 23, method 300 includes a block 304 where a first dummy electrode 210 is selectively removed to form a gate recess 228. Operations at block 304 are substantially similar to those at block 104. For brevity, the detailed description of the operations at block 304 is omitted. Operations at block 304 include formation and patterning of the hard mask layer 226 (shown in FIG. 22) and etching of the first dummy electrode 210 (shown in FIG. 23). The selective removal of the first dummy electrode 210 forms an opening 227.

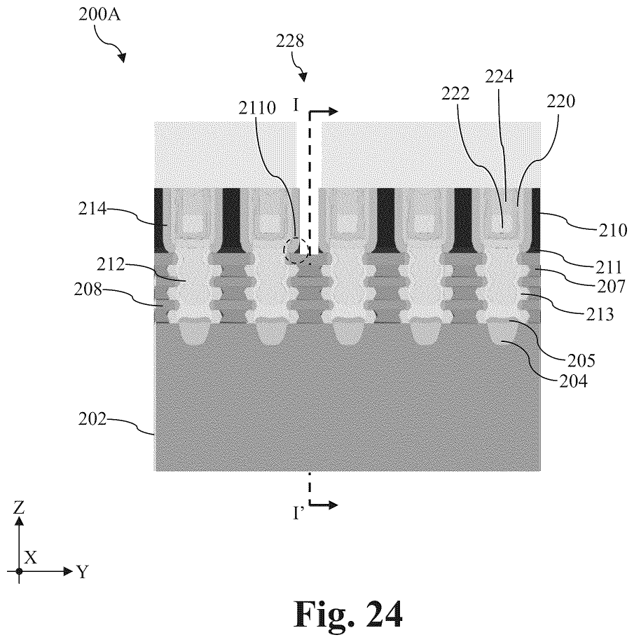

Referring to FIGS. 21 and 24, method 300 includes a block 306 where a dummy dielectric layer 211 is etched to expose a topmost channel layer 208. Operations at block 306 are substantially similar to those at block 106. For brevity, the detailed description of the operations at block 306 is omitted. Operations at block 306 form a gate recess 228 and the topmost channel layer 208 is exposed in the gate recess 228. Due to the anisotropic nature of the etch at block 306, residual dummy dielectric layer 2110 may remain between the topmost channel layer 208 and the gate spacer 214. In alternative embodiments not shown in the figures, when both isotropic etch and anisotropic etch are implemented at block 306, the residual dielectric layer 2110 may be completely removed.

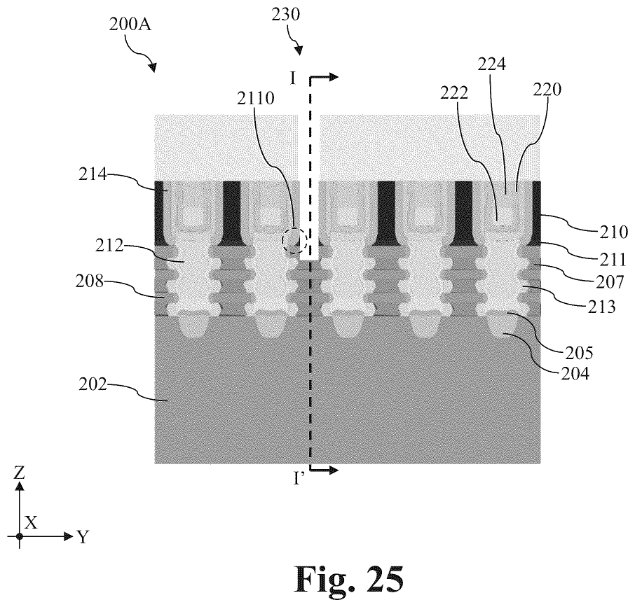

Referring to FIGS. 21 and 25, method 300 includes a block 308 where the topmost channel layer 208 is etched in the gate recess 228. After operations at block 306 expose the topmost channel layers 208 in the gate recess 228, a dry etch is performed to etch through the topmost channel layers 208 to form an extended gate recess 230. To prevent premature damages to the semiconductor sacrificial layer 207, the dry etch is configured to be selective to Si and etches SiGe at a slower rate. An example dry etch process for block 308 may include use of tetrafluoromethane (CF₄), oxygen (O₂), nitrogen (N₂), argon (Ar), or a combination thereof. As shown in FIG. 25, because the etch processes at blocks 304, 306 and 308 are directional, sidewalls of the extended gate recess 230 are substantially perpendicular.

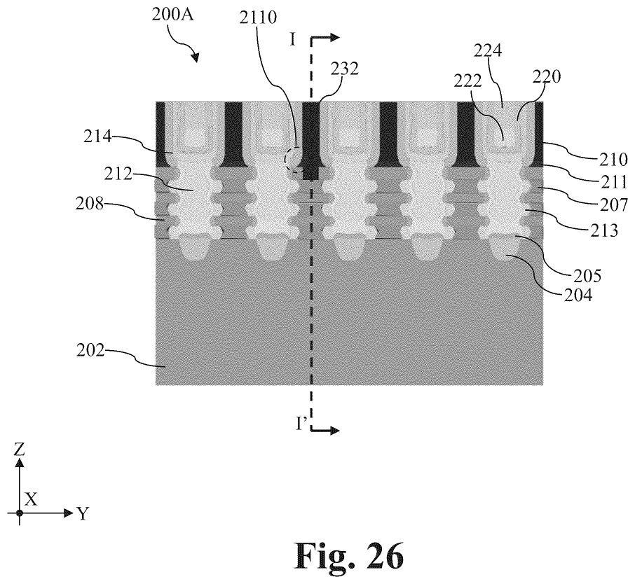

Referring to FIGS. 21 and 26, method 300 includes a block 310 where a polysilicon backfill 232 is deposited to fill the gate recess 228. Operations at block 310 are substantially similar to those at block 110. For brevity, the detailed description of the operations at block 310 is omitted. As shown in FIG. 26, the polysilicon backfill 232 may interface the residual dummy dielectric layer 2110.

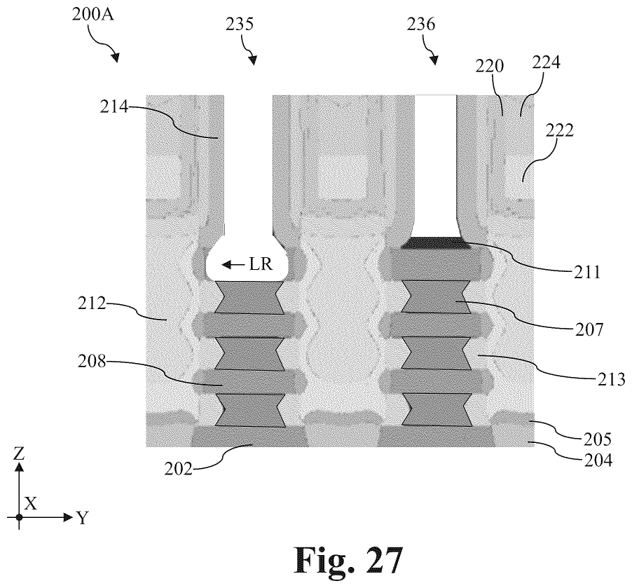

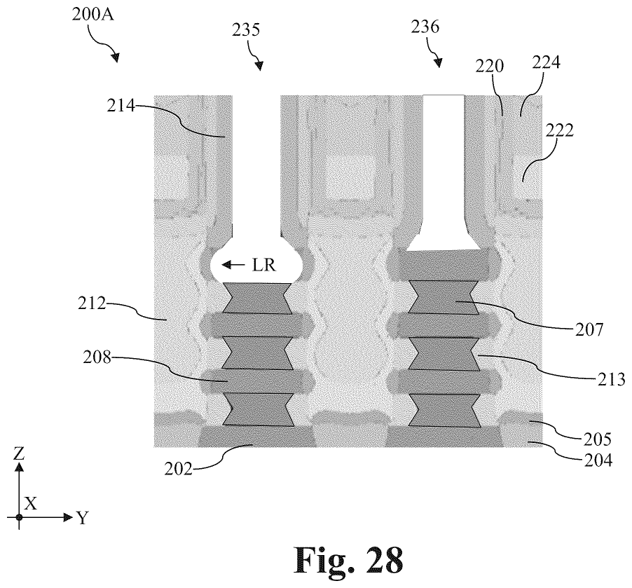

Referring to FIGS. 21, 27, 28, and 29, method 300 includes a block 312 where dummy electrodes 210, the polysilicon backfill 232, and semiconductor sacrificial layers 207 are selectively removed to release the channel layers 208. With the polysilicon backfill 232 formed at block 310 to provide a uniform environment, a wet etch process is performed at block 312 to selectively and isotropically remove the polysilicon backfill 232 and other dummy electrodes 210, as illustrated in FIG. 27. In some embodiments, the wet etch at block 312 may include use of a tetramethylammonium hydroxide (TMAH) solution, a potassium hydroxide (KOH) solution, hydrofluoric acid, nitric acid, or a combination thereof. FIG. 27 illustrates a cross-sectional view of the precursor structure 200. As shown in FIG. 27, the removal of the polysilicon backfill 232 form a third gate opening 235 and the removal of the dummy electrode 210 forms a second gate opening 236. Because the wet etch is selective to the channel layers 208, the wet etch may attack the topmost channel layer 208 under the gate spacer 214, forming a lateral recess LR. The lateral recess LR undercuts the gate spacer 214. Referring still to FIG. 28, the topmost channel layer 208 is substantially removed from the third gate opening 235 while the topmost channel layer 208 remains in the second gate opening 236. A topmost portion of the semiconductor sacrificial layers 207 is exposed in the third gate opening 235.

Referring to FIG. 28, after the removal of the polysilicon backfill 232 and the dummy electrodes 210, the dummy dielectric layer 211 exposed in the second gate opening 236 is selectively removed. At block 312, a separate etch process may be performed to selectively remove the dummy dielectric layer 211. In some embodiment, the etching of the dummy dielectric layer 211 may be a dry etch process that implements oxygen (O₂), hydrogen (H₂), argon (Ar), a fluorine-carbon gas (e.g., CF₄, CH₂F₂, CHF₃, C₄F₈, C₅F₈, and/or C₂F₆), or a combination thereof. For example, a selective wet etch process or a selective dry etch process may be performed to remove the dummy dielectric layer 211.

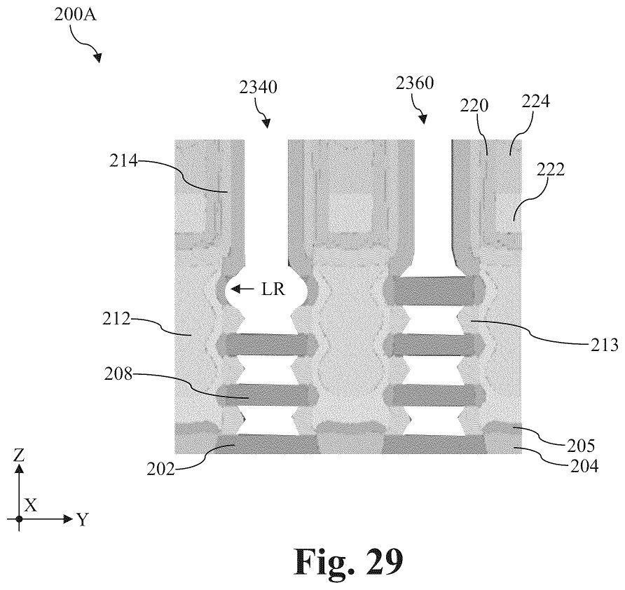

Reference is then made to FIG. 29. After the removal of the dummy dielectric layer 211 in the second gate opening 236, the semiconductor sacrificial layers 207 are selectively removed to release the channel layers 208. In some implementations, the selective removal of the semiconductor sacrificial layers 207 may be achieved using a selective wet etching. In some embodiments, the selective wet etching may include an APM etch (e.g., ammonia hydroxide-hydrogen peroxide-water mixture). Reference is made to FIG. 29. The selective removal of the semiconductor sacrificial layers 207 in the third gate opening 235 (shown in FIG. 27) forms a first gate trench 2340 that includes the lateral recess LR. The selective removal of the semiconductor sacrificial layers 207 and the dummy dielectric layer 211 in the second gate opening 236 (shown in FIG. 27) forms a second gate trench 2360.

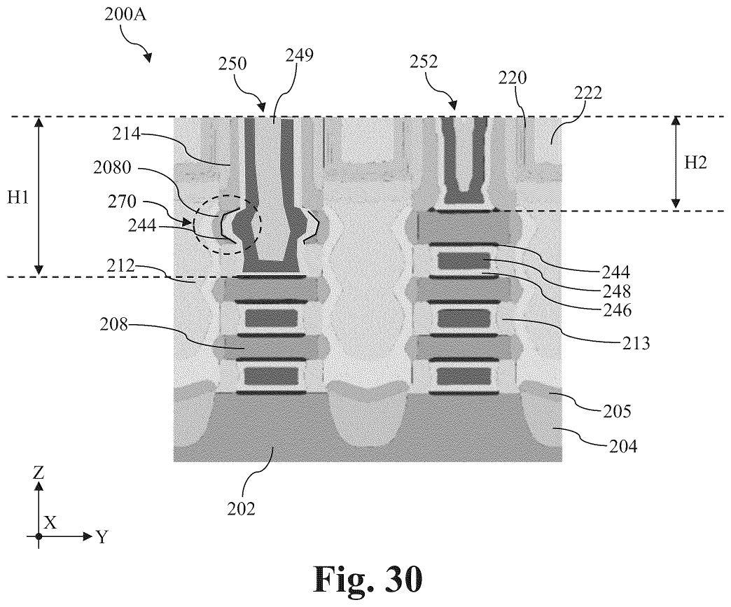

Referring to FIGS. 21 and 30, method 300 includes a block 314 where a gate structure is formed to wrap around the channel layers 208. Operations at block 314 are substantially similar to those at block 114. For brevity, the detailed description of the operations at block 314 is omitted. Due to presence of the lateral recess LR, the first gate structure 250 includes a lateral bulge 270 at the level of the recessed topmost channel layer 208. As shown in FIG. 30, the lateral bulge 270 includes a channel layer residue 2080, the interfacial layer 244 formed on the channel layer residue 2080, the gate dielectric layer 246, and the gate electrode 248. In some embodiments illustrated in FIG. 30, the gate spacer 214 is disposed directly over and interfaces the lateral bulge 270.

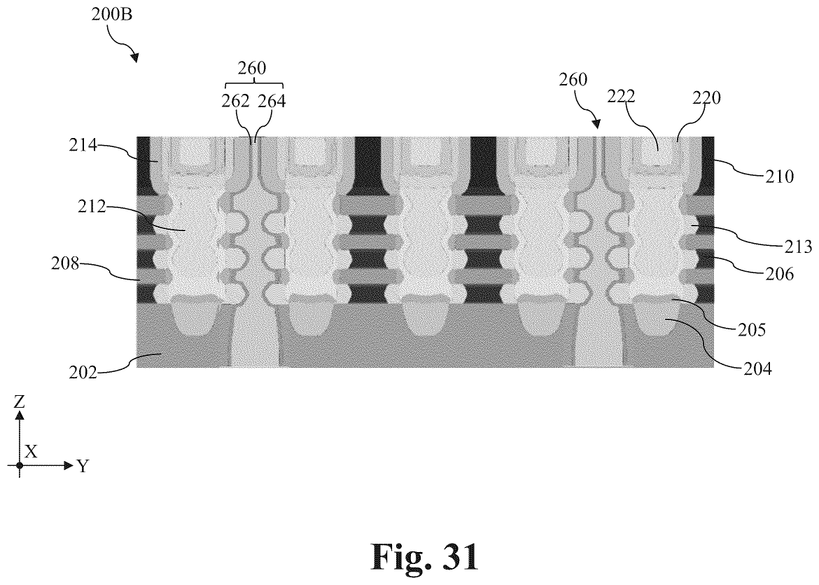

FIG. 31 illustrates a precursor structure 200B having isolation structures 260. As shown in FIG. 31, the dummy gate electrodes 210 in the precursor structure 200B are still present while processes have been performed to form the isolation structures 260. In some example processes, an isolation structure 260 may be formed by etching away a dummy gate structure 210 as well as channel layers 208 and semiconductor sacrificial layers below the dummy gate structure 210 to form an isolation opening that extends into the substrate 202. Then a first dielectric layer 262 and a second dielectric layer 264 are subsequently deposited over the isolation opening. It should be noted that the formation of the isolation structure may take place before the formation of the dielectric interposers 206, which replace the semiconductor sacrificial layers. This is so because it is easier to selectively remove the channel layers 208 and the semiconductor sacrificial layers, both of which are formed semiconductor materials. The isolation structures 260 extend into the substrate 202 to isolate different active regions. They may also be referred to as continuous poly on diffusion edge (CPODE) features 260. The first dielectric layer 262 and the second dielectric layer 264 are different in terms of oxygen content and dielectric constant. The first dielectric layer 262 has a smaller oxygen content and a greater dielectric constant than the second dielectric layer 264. In some embodiments, the first dielectric layer 262 may include silicon nitride and the second dielectric layer 264 may include silicon oxide.

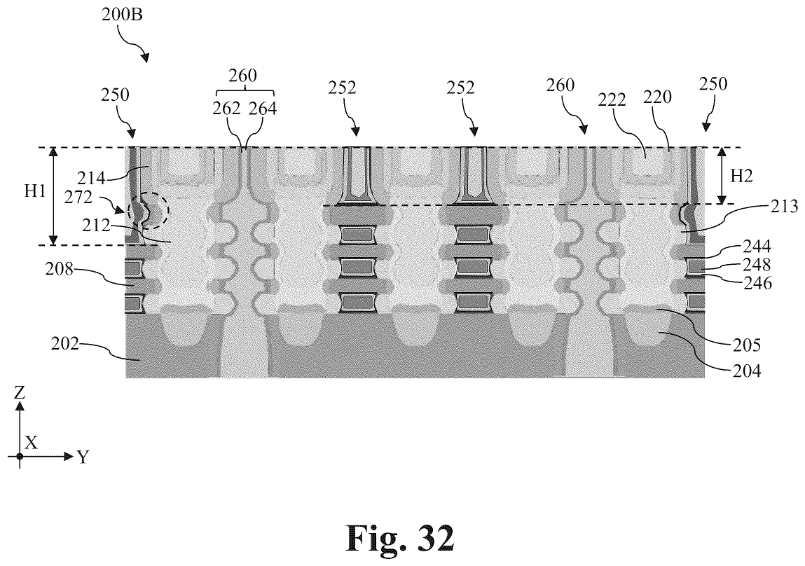

Operations in methods 100 and 300 may be performed to the precursor structure 200B to form the first gate structure 250 and the second gate structure 252, as shown in FIG. 32. As described above, the first gate structure 250 wraps around two suspended channel layers 208 and the second gate structure 252 wraps around three suspended channel layers 208. Because the first gate structure 250 wraps around one less channel layer 208, a first height H1 of the top portion of the first gate structure 250 is greater than a second height H2 of the top portion of the second gate structure 252. In some instances, the first height H1 is greater than the second height H2 by a difference between about 10 nm and about 30 nm. This difference is substantially equal to a sum of a thickness of the channel layer 208 and a spacing between two channel layers 208. The first gate structure 250 may include a lateral bulge 270 at the level of the recessed topmost channel layer 208. In embodiments depicted in FIG. 32, the gate spacer 214 is disposed directly over and interfaces the lateral bulge 270.

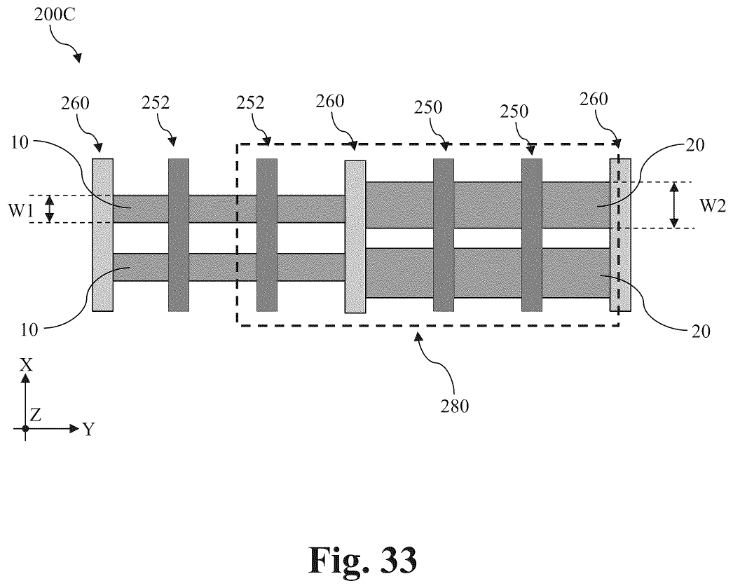

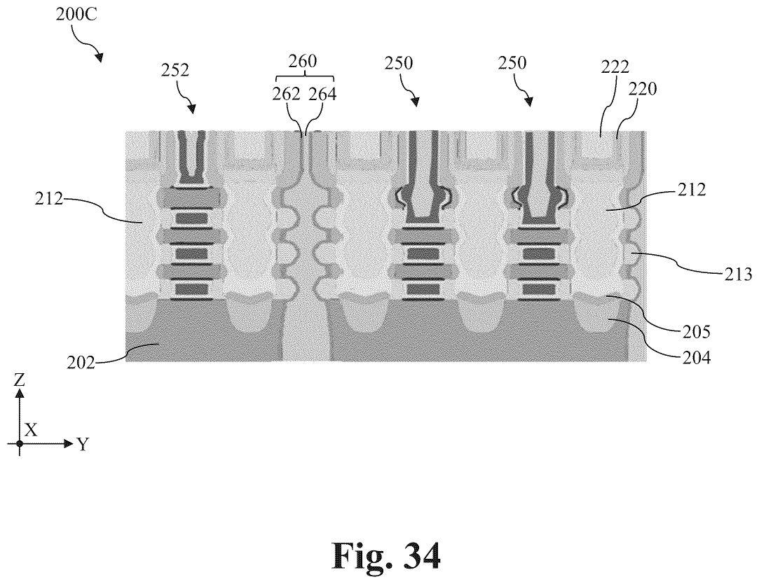

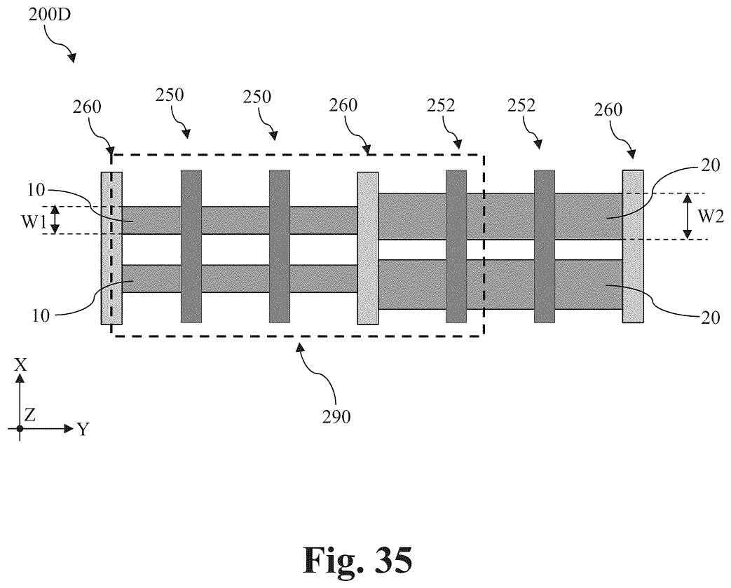

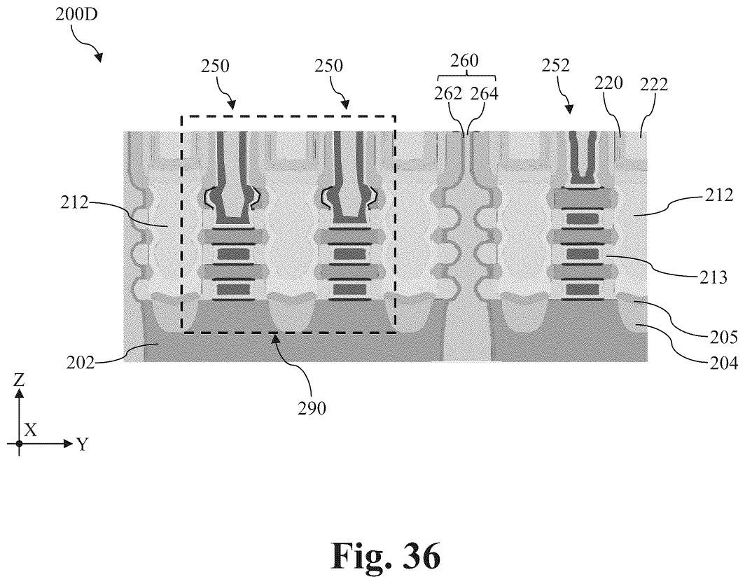

Channel widths also affect device capacitance. In general, a smaller channel width may lead to reduced primary and secondary capacitance and a greater channel width may lead to increased primary and secondary capacitance. The removal of the topmost channel layer described above may be implemented to active regions with different widths. FIGS. 33 and 34 illustrate an example embodiment where the second gate structure 252 are implemented to a first active region 10 having a smaller first channel width W1 and the first gate structures 250 are implemented to a second active region 20 having a greater second channel width W2. FIGS. 35 and 36 illustrate another example embodiment where the first gate structure 250 are implemented to a first active region 10 having a smaller first channel width W1 and the second gate structures 252 are implemented to a second active region 20 having a greater second channel width W2.

Reference is first made to FIGS. 33 and 34, which illustrates a semiconductor structure 200C. The semiconductor structure 200C includes first active regions 10 and second active regions 20. Each of the first active regions 10 and the second active regions 20 extend lengthwise along the Y direction. As shown in the top view in FIG. 33, each of the first active regions 10 is aligned with a second active region 2 along the Y direction. Additionally, the first active regions 10 are isolated from the second active regions 20 by an isolation structure 260. Along the X direction, the first active region 10 includes a first width W1 and the second active region 20 includes a second width W2 greater than the first width W1. In some embodiments, a ratio of the second width W2 and the first width W1 is between about 1.1 and about 2.0. The semiconductor structure 200C includes first gate structure 250 (similarly shown in FIGS. 15 and 30) disposed over the second active regions 20 and second gate structure 252 (similarly shown in FIGS. 15 and 30) disposed over the first active region 10. A fragmentary cross-sectional view of a device region 280 in FIG. 33 is shown in FIG. 34.

Reference is then made to FIGS. 35 and 36, which illustrates a semiconductor structure 200D. The semiconductor structure 200D includes first active regions 10 and second active regions 20. Each of the first active regions 10 and the second active regions 20 extend lengthwise along the Y direction. As shown in the top view in FIG. 35, each of the first active regions 10 is aligned with a second active region 2 along the Y direction. Additionally, the first active regions 10 are isolated from the second active regions 20 by an isolation structure 260. Along the X direction, the first active region 10 includes a first width W1 and the second active region 20 includes a second width W2 greater than the first width W1. In some embodiments, a ratio of the second width W2 and the first width W1 is between about 1.1 and about 2.0. The semiconductor structure 200D includes first gate structure 250 (similarly shown in FIGS. 15, 19 and 30) disposed over the first active regions 10 and second gate structure 252 (similarly shown in FIGS. 15, 19 and 30) disposed over the second active region 20. A fragmentary cross-sectional view of a device region 280 in FIG. 36 is shown in FIG. 35.

In one exemplary aspect, the present disclosure is directed to a semiconductor device. The semiconductor device includes a base fin, a plurality of nanostructures disposed over the base fin, a gate structure wrapping around the plurality of nanostructures, a gate spacer disposed along a sidewall of a top portion of the gate structure, and a source/drain feature interfacing end sidewalls of the plurality of nanostructures. The gate structure includes a bulge portion that laterally extends below the gate spacer and the gate structure includes a titanium-based material.

In some embodiments, the semiconductor device further includes a plurality of inner spacer features interleaving the plurality of nanostructures. The bulge portion partially extends between a topmost one of the plurality of inner spacer features and the gate spacer. In some embodiments, the bulge portion is spaced apart from the source/drain feature by a semiconductor layer. In some implementations, the semiconductor layer includes silicon. In some instances, the semiconductor device further includes an undoped semiconductor feature disposed below the source/drain feature. The undoped semiconductor feature interfaces a sidewall of the base fin. In some implementations, the semiconductor device further includes a bottom dielectric layer disposed between a bottom surface of the source/drain feature and a top surface of the undoped semiconductor feature. In some embodiments, the gate structure includes an interfacial layer, a gate dielectric layer over the interfacial layer, and a work function metal over the gate dielectric layer. A portion of the interfacial layer interfaces the semiconductor layer. In some embodiments, the portion of the interfacial layer interfaces the gate spacer.

In another exemplary aspect, the present disclosure is directed to a semiconductor structure. The semiconductor structure includes a first base fin and a second base fin, a first number of nanostructures disposed over the first base fin, a second number of nanostructures disposed over the second base fin, a first gate structure wrapping around each of the first number of nanostructures, a second gate structure wrapping around each of the second number of nanostructures, and a source/drain feature disposed between and interfacing end sidewalls of the first number of nanostructures and end sidewalls of the second number of nanostructures. A top surface of a topmost one of the first number of nanostructures is lower than a top surface of a topmost one of the second number of nanostructures. The first number is different from the second number and the source/drain feature includes multiple layers.

In some embodiments, the first number is smaller than the second number. In some embodiments, the first number of nanostructures include two nanostructures and the second number of nanostructures include three nanostructures. In some implementations, the semiconductor structure further includes a first gate spacer disposed along a sidewall of a top portion of the first gate structure, and a second gate spacer disposed along a sidewall of a top surface of the second gate structure. The first gate structure includes a bulge portion that laterally extends below the first gate spacer. In some embodiments, the bulge portion is spaced apart from the source/drain feature by a semiconductor layer. In some embodiments, the semiconductor layer includes silicon. In some embodiments, the semiconductor structure further includes an undoped semiconductor feature disposed below the source/drain feature. The undoped semiconductor feature interfaces a sidewall of the first base fin and a sidewall of the second base fin. In some embodiments, the semiconductor structure further includes a bottom dielectric layer disposed between a bottom surface of the source/drain feature and a top surface of the undoped semiconductor feature.

In yet another exemplary aspect, the present disclosure is directed to a method. The method includes forming a first stack of channel layers interleaved by a first plurality of sacrificial dielectric layers, forming a second stack of channel layers interleaved by a second plurality of sacrificial dielectric layers, forming a first dummy gate stack over the first stack of channel layers, forming a second dummy gate stack over the second stack of channel layers, selectively removing the first dummy gate stack, removing a topmost one of the first stack of channel layers to form a gate recess, depositing a backfill over the gate recess, after the removing of the topmost one of the first stack of channel layers, removing the second dummy gate stack, removing the first plurality of sacrificial dielectric layers to release a rest of the first stack of channel layers as first nanostructures, selectively removing the second plurality of sacrificial dielectric layers to release the second stack of channel layers as second nanostructures, and forming a first gate structure to wrap around each of the first nanostructures and a second gate structure to wrap around each of the second nanostructures. The first gate structure includes a titanium-based material.

In some embodiments, the method further includes before the removing the second dummy gate stack, depositing a backfill over the gate recess. The removing of the second dummy gate stack includes removing the backfill. In some embodiments, the first plurality of sacrificial dielectric layers and the second plurality of sacrificial dielectric layers include silicon oxide. In some implementations, the precursor structure includes a gate spacer disposed along a sidewall of a top portion of the first dummy gate stack and the removing of the topmost one of the first stack of channel layers includes laterally etching the topmost one of the first stack of channel layers to undercut the gate spacer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a base fin;
a plurality of nanostructures disposed over the base fin;
a gate structure wrapping around the plurality of nanostructures;
a gate spacer disposed along a sidewall of a top portion of the gate structure; and
a source/drain feature interfacing end sidewalls of the plurality of nanostructures,
wherein the gate structure comprises a bulge portion that laterally extends below the gate spacer,
wherein the gate structure comprises a titanium-based material.

2. The semiconductor device of claim 1, further comprising:
a plurality of inner spacer features interleaving the plurality of nanostructures,
wherein the bulge portion partially extends between a topmost one of the plurality of inner spacer features and the gate spacer.

3. The semiconductor device of claim 1, wherein the bulge portion is spaced apart from the source/drain feature by a semiconductor layer.

4. The semiconductor device of claim 3, wherein the semiconductor layer comprises silicon.

5. The semiconductor device of claim 1, further comprising:
an undoped semiconductor feature disposed below the source/drain feature,
wherein the undoped semiconductor feature interfaces a sidewall of the base fin.

6. The semiconductor device of claim 5, further comprising:
a bottom dielectric layer disposed between a bottom surface of the source/drain feature and a top surface of the undoped semiconductor feature.

7. The semiconductor device of claim 3,
wherein the gate structure comprises an interfacial layer, a gate dielectric layer over the interfacial layer, and a work function metal over the gate dielectric layer,
wherein a portion of the interfacial layer interfaces the semiconductor layer.

8. The semiconductor device of claim 7, wherein the portion of the interfacial layer interfaces the gate spacer.

9. A semiconductor structure, comprising:
a first base fin and a second base fin;
a first number of nanostructures disposed over the first base fin;
a second number of nanostructures disposed over the second base fin;
a first gate structure wrapping around each of the first number of nanostructures;
a second gate structure wrapping around each of the second number of nanostructures; and
a source/drain feature disposed between and interfacing end sidewalls of the first number of nanostructures and end sidewalls of the second number of nanostructures,
wherein a top surface of a topmost one of the first number of nanostructures is lower than a top surface of a topmost one of the second number of nanostructures,
wherein the first number is different from the second number,
wherein the source/drain feature comprises multiple layers.

10. The semiconductor structure of claim 9, wherein the first number is smaller than the second number.

11. The semiconductor structure of claim 9,
wherein the first number of nanostructures comprise two nanostructures,
wherein the second number of nanostructures comprise three nanostructures.

12. The semiconductor structure of claim 9, further comprising:
a first gate spacer disposed along a sidewall of a top portion of the first gate structure; and
a second gate spacer disposed along a sidewall of a top surface of the second gate structure,
wherein the first gate structure comprises a bulge portion that laterally extends below the first gate spacer.

13. The semiconductor structure of claim 12, wherein the bulge portion is spaced apart from the source/drain feature by a semiconductor layer.

14. The semiconductor structure of claim 13, wherein the semiconductor layer comprises silicon.

15. The semiconductor structure of claim 9, further comprising:
an undoped semiconductor feature disposed below the source/drain feature,
wherein the undoped semiconductor feature interfaces a sidewall of the first base fin and a sidewall of the second base fin.

16. The semiconductor structure of claim 15, further comprising:
a bottom dielectric layer disposed between a bottom surface of the source/drain feature and a top surface of the undoped semiconductor feature.

17. A method, comprising:
forming a first stack of channel layers interleaved by a first plurality of sacrificial dielectric layers;
forming a second stack of channel layers interleaved by a second plurality of sacrificial dielectric layers;
forming a first dummy gate stack over the first stack of channel layers;
forming a second dummy gate stack over the second stack of channel layers;
selectively removing the first dummy gate stack;
removing a topmost one of the first stack of channel layers to form a gate recess;
depositing a backfill over the gate recess;
after the removing of the topmost one of the first stack of channel layers, removing the second dummy gate stack;
removing the first plurality of sacrificial dielectric layers to release a rest of the first stack of channel layers as first nanostructures;
selectively removing the second plurality of sacrificial dielectric layers to release the second stack of channel layers as second nanostructures; and
forming a first gate structure to wrap around each of the first nanostructures and a second gate structure to wrap around each of the second nanostructures,
wherein the first gate structure comprises a titanium-based material.

18. The method of claim 17, further comprising:
before the removing the second dummy gate stack, depositing a backfill over the gate recess,
wherein the removing of the second dummy gate stack comprises removing the backfill.

19. The method of claim 17, wherein the first plurality of sacrificial dielectric layers and the second plurality of sacrificial dielectric layers comprise silicon oxide.

20. The method of claim 17,
wherein the precursor structure comprises a gate spacer disposed along a sidewall of a top portion of the first dummy gate stack,
wherein the removing of the topmost one of the first stack of channel layers comprises laterally etching the topmost one of the first stack of channel layers to undercut the gate spacer.
